(19) United States
(12) Patent Application Publication
(10) Pub. No.: US 2013/0241374 A1
(43) Pub. Date: Sep. 19, 2013

(54) Isolation Device

(71) Applicant: UNIHAN CORPORATION, Taipei (TW)

(72) Inventor: Wei-Chun Tsao, Taipei (TW)

(73) Assignee: UNIHAN CORPORATION, Taipei (TW)

(21) Appl. No.: 13/779,695

(22) Filed: Feb. 27, 2013

(30) Foreign Application Priority Data
Mar. 16, 2012 (TW) 101204861

(51) Int. Cl. H05K 5/00; H05K 5/02

(52) U.S. Cl. CPC H05K 5/0004; H05K 5/0217
USPC 312/223.1

(57) ABSTRACT

An isolation device includes a frame body and a cover body. The frame body is formed through stamping, and includes a base body and an abutting member. The abutting member is connected at a periphery at a side of the base body. The cover body includes a main body and a clamping member. The clamping member is connected at a periphery of the main body, and is inserted in the frame body at the cover body. The abutting member abuts tightly against the clamping member, thereby seamlessly integrating the cover body and the frame body. After the cover body is inserted in the frame body, the abutting member abuts tightly against the clamping member, achieving a seamless integration effect.

### CROSS-REFERENCES TO RELATED APPLICATIONS

This non-provisional application claims priority under 35 U.S.C. §119(a) on Patent Application No. 101204861 filed in Taiwan, R.O.C. on Mar. 16, 2012, the entire contents of which are hereby incorporated by reference.

### BACKGROUND OF THE INVENTION

1. Technical Field

The present invention relates to an isolation device, and in particular, to an isolation device that is completely isolated from the outside after being assembled.

2. Related Art

A common isolator is loaded on a printed circuit board (PCB) and used to connect electronic components on the PCB. Please refer to FIG. 1, FIG. 1 is a schematic structural view of a conventional isolator. A conventional isolator A1 consists of an upper cover A11, a bottom frame A12, and a terminal portion A13. The upper cover A11 is a board that forms four side plates A112 at four side edges of a main body A111 through bending, and a plurality of position bumps A113 is provided on an internal side surface of the side plates A112. The bottom frame A12 is formed through bending a board, and after bending, an extending sheet A121 at one side edge is fixed with another side edge, presenting a rectangular shape. In addition, an external side surface of the bottom frame A12 is provided with a plurality of position concave portions A122, and is provided with a via hole A123 at a proper position used for the terminal portion A13 to pass through.

When the upper cover A11 is integrated with the bottom frame A12, four side plates A112 of the upper cover A11 cover the external side surface of the bottom frame A12, and the plurality of position bumps A113 is inserted in the corresponding position concave portions A122, so as to fix the upper cover A11 on the bottom frame A12. However, although the conventional bottom frame A12 is fixed through the extending sheet A121 and presents a rectangular shape, seams may appear at fixing joints due to different fixing manners. Furthermore, after the isolator A1 is assembled, seams may appear between the side plates A112 at four side edges of the upper cover A11 and the bottom frame A12 because the upper cover A11 and the bottom frame A12 cannot be integrated tightly. These seams lead to electric wave intrusion or leakage, affecting the communication. In addition, the conventional bottom frame A12 is formed through bending a board, resulting in a poor structural strength. Even a slight force applied on the bottom frame A12 produces a concavity thereon.

### SUMMARY

Accordingly, an embodiment of the present invention provides an isolation device, which includes a frame body and a cover body. The frame body is formed through stamping, and includes a base body and an abutting member. The abutting member is connected at a periphery at a side of the base body. The cover body includes a main body and a clamping member. The clamping member is connected at a periphery of the main body, and is inserted in the frame body at the cover body. The abutting member abuts tightly against the clamping member, thereby seamlessly integrating the cover body and the frame body.

The efficacy of the embodiment of the present invention lies in that, after the cover body is inserted in the frame body, the abutting member abuts tightly against the clamping member, achieving a seamless integration effect. Additionally, the frame body has a seamless structure formed through stamping, avoiding the seam at each joint in the conventional isolator. Furthermore, the frame body is formed through stamping. Therefore, with the same thickness, the structural strength of the frame body is better than that of the conventional isolator. The frame body can desirably prevent an external force from producing a concavity thereon.

Detailed characteristics and advantages of the present invention are described in detail in the following embodiments. The content is sufficient for any person skilled in the art to understand and implement the technical content of the present invention. In addition, according to the content disclosed in the specification of the present invention, the scope of the patent application and the drawings, any person skilled in the art can easily understand the related objects and advantages of the present invention.

### BRIEF DESCRIPTION OF THE DRAWINGS

The present invention will become more fully understood from the detailed description given herein below for illustration only, and thus not limitative of the present invention, wherein:

FIG. 1 is a schematic structural view of a conventional isolator;

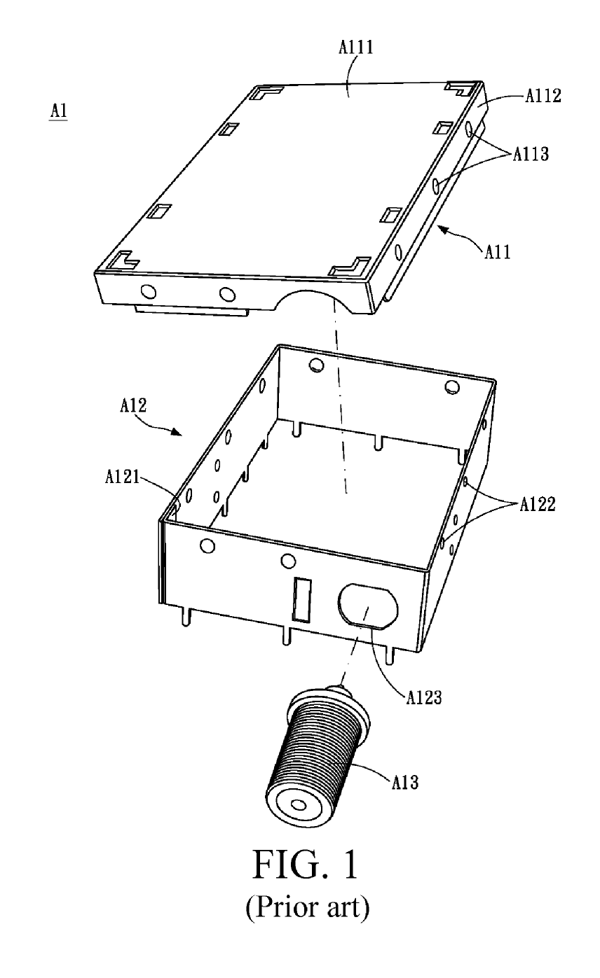

FIG. 2 is a schematic exterior view of an embodiment of the present invention;

FIG. 3 is an exploded exterior view of an embodiment of the present invention;

FIG. 4 is an exploded schematic view from another viewing angle of an embodiment of the present invention;

FIG. 5 is a partial sectional schematic view during assembly of an embodiment of the present invention; and

FIG. 6 is a sectional schematic view during assembly of an embodiment of the present invention.

### DETAILED DESCRIPTION

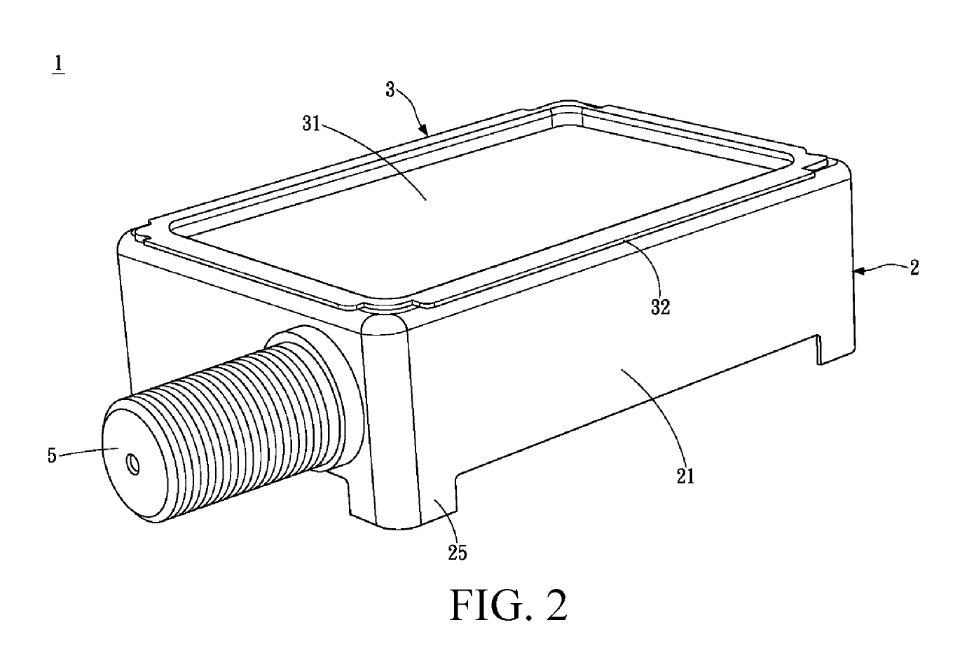

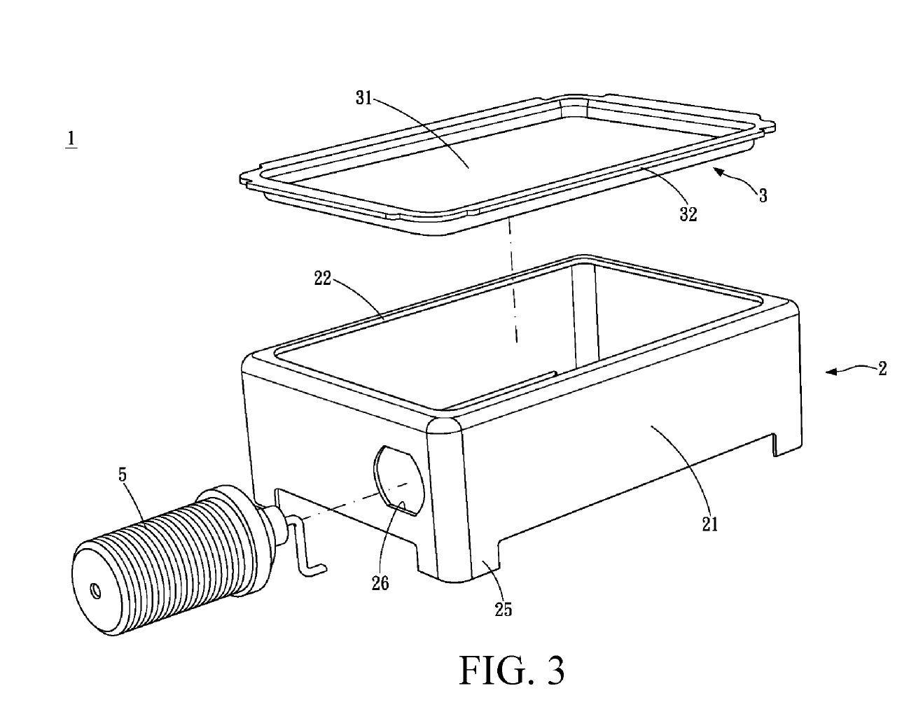

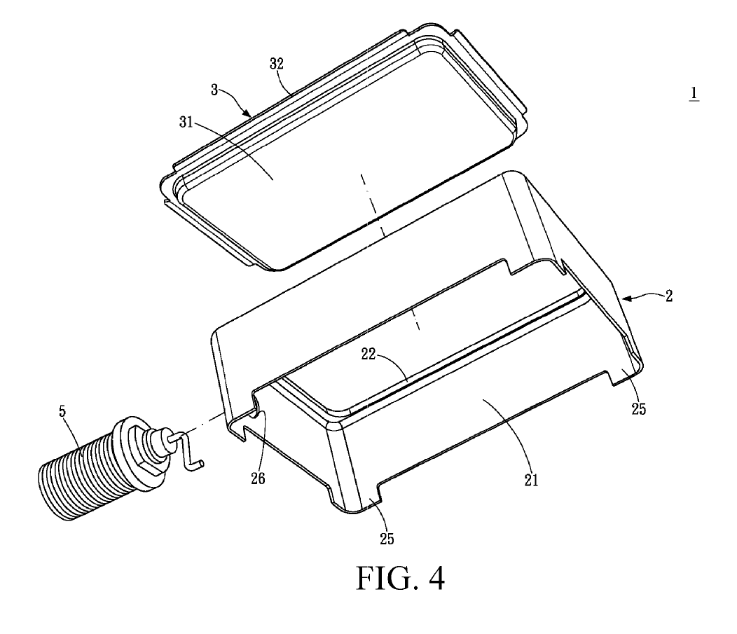

Please refer to FIG. 2, FIG. 3 and FIG. 4. FIG. 2 is a schematic exterior view of an embodiment of the present invention, FIG. 3 is an exploded schematic view of an embodiment of the present invention, and FIG. 4 is an exploded schematic view from another viewing angle of an embodiment of the present invention. An isolation device 1 according to an embodiment of the present invention includes a frame body 2 and a cover body 3.

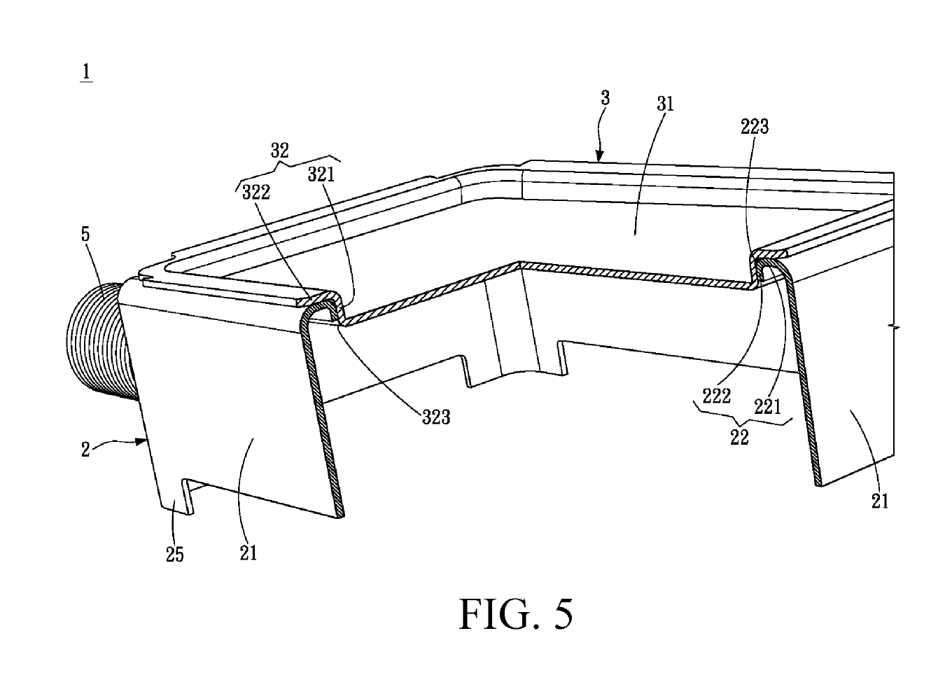

The frame body 2 is made of a metal material, and is formed through stamping. Seen as a whole, the frame body 2 presents a rectangular shape (as shown in FIG. 4). Relevant electronic components may be disposed in the frame body 2, which are not specifically limited herein. The frame body 2 mainly consists of a base body 21 and an abutting member 22. The base body 21 is a hollow body. The abutting member 22 is connected at a periphery at a side of the base body 21, and extends from the periphery towards a central position of the base body 21. The abutting member 22 mainly consists of a connection portion 221 and an abutting portion 222. The connection portion 221 is substantially perpendicular to the base body 21; an end of the connection portion 221 is connected at a periphery of the base body 21, and the other end is connected to the abutting portion 222. The abutting portion 222 is substantially perpendicular to the connection portion 221, and extends from the connection portion 221 to a bottom portion of the base body 21. In addition, an arc lead angle 223 may be provided at an outer edge of a joint between the connection portion 221 and the abutting portion 222 (as shown in FIG. 5). The structure of the abutting member 22 described above is merely an example, and the present invention is not limited thereto. The composition and structure thereof may be changed according to actual design requirements, for example, the abutting member 22 is a flat board and connected at the base body 21 in a perpendicular manner, and a block corner thereof may be a round angle.

In this embodiment, the frame body 2 is formed with a plurality of pins 25 at the bottom portion of the base body 21 through stamping, in which the plurality of pins 25 is formed at four block corners of the base body 21. In addition, one side wall of the base body 21 of the frame body 2 is provided with a hole-shaped via portion 26, and the via portion 26 is used for a terminal member 5 to pass through. The terminal member 5 herein is fastened on the base body 21 through stamping, and a tin sheet (not shown) may be disposed therebetween to enhance the torsion performance. Additionally, fused tin fills a contact seam between metals.

The cover body 3 is made of a metal material and may be integrally formed through stamping. Seen as a whole, the cover body 3 is saucer-shaped (as shown in FIG. 3). The cover body 3 mainly consists of a main body 31 and a clamping member 32. The main body 31 is basically a rectangular sheet body, and the clamping member 32 is connected at a periphery of the main body 31. The abutting member 22 and the clamping member 32 are designed to tightly fit with each other. When the cover body 3 is inserted in the frame body 2, the abutting member 22 can tightly abut against the clamping member 32, thereby seamlessly integrating the cover body 3 and the frame body 2. The clamping member 32 mainly consists of a butting portion 321 and an extending portion 322. The butting portion 321 is substantially perpendicular to the main body 31; an end of the butting portion 321 is connected at a periphery of the main body 31, and the other end is connected to the extending portion 322. Additionally, the extending portion 322 is substantially perpendicular to the butting portion 321, and extends outward from the butting portion 321. In addition, an arc lead portion 323 may be provided at an outer edge of a joint between the butting portion 321 and the main body 31 (as shown in FIG. 5). The structure of the clamping member 32 described above is merely an example, and the present invention is not limited thereto. The composition and structure thereof may be changed according to actual design requirements, for example, the clamping member 32 is a flat board and connected at the main body 31 in a perpendicular manner, and a block corner thereof may be a round angle.

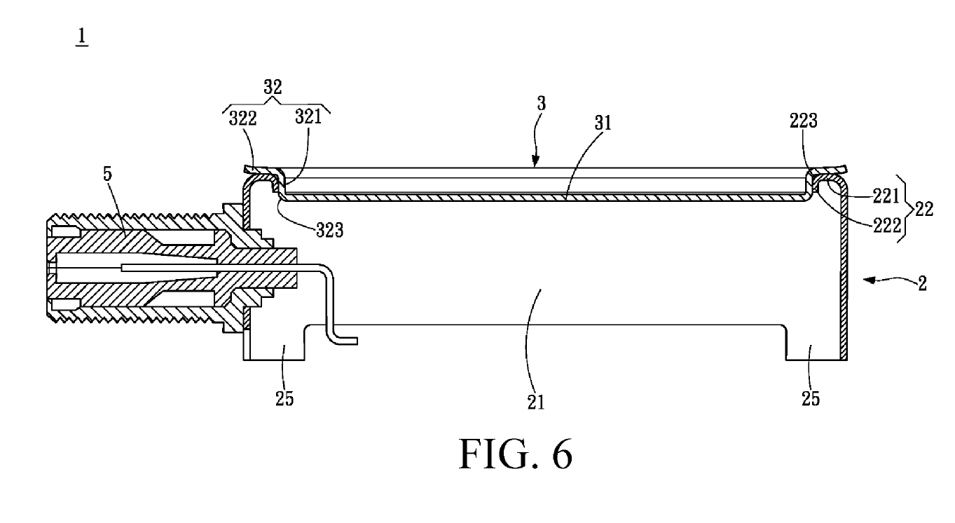

Please refer to FIG. 5 and FIG. 6. FIG. 5 is a partial sectional schematic view during assembly of an embodiment of the present invention, and FIG. 6 is a sectional schematic view during assembly of an embodiment of the present invention. During assembly, the cover body 3 is inserted in the frame body 2, the lead portion 323 of the cover body 3 leans against the lead angle 223 of the frame body 2, and a force is applied to enable the lead portion 323 to move along the lead angle 223 and to be gradually inserted in the frame body 2. During the displacement, the lead angle 223 moves along a wall of the abutting portion 222. After assembly, the butting portion 321 of the cover body 3 is tightly adhered to the abutting portion 222 of the frame body 2, and covering the connection portion 221 of the frame body 2 through the extending portion 322. The butting portion 321 is tightly adhered to the abutting portion 222, so that the cover body 3 and the frame body 2 are seamlessly integrated.

In the foregoing description, the block corners between the abutting member 22 and the clamping member 32 being round angles is merely an illustrative example to make the assembly of the cover body 3 and the frame body 2 easier, but the present invention is not limited thereto. The block corners between the abutting member 22 and the clamping member 32 may be right angles or other structures.

The abutting member abuts tightly against the clamping member, achieving a seamless integration effect. Additionally, the frame body has a seamless structure formed through stamping, avoiding the seam at each joint in the conventional isolator. Furthermore, the frame body is formed through stamping. Therefore, with the same thickness, the structural strength of the frame body is better than that of the conventional isolator. The frame body can desirably prevent an external force from producing a concavity thereon.

While the present invention has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. An isolation device, comprising:
a frame body, comprising a base body and an abutting member, the abutting member being connected at a periphery of the base body; and
a cover body, comprising a main body and a clamping member, the clamping member being connected at a periphery of the main body, the cover body being inserted in the frame body, and the abutting member tightly abutting against the clamping member, thereby seamlessly integrating the cover body and the frame body.

2. The isolation device according to claim 1, wherein the abutting member comprises a connection portion and an abutting portion, the connection portion connecting the base body and the abutting portion, and the cover body covering the frame body, the abutting portion being tightly adhered to the clamping member.

3. The isolation device according to claim 2, wherein the abutting member further comprises a lead angle located at a joint portion between the connection portion and the abutting portion, and used to guide the clamping member of the cover body to enter the abutting portion.

4. The isolation device according to claim 1, wherein the clamping member further comprises a butting portion and an extending portion, the butting portion connecting the main body and the extending portion, and the cover body covering the frame body, the butting portion being tightly adhered to the abutting member.

5. The isolation device according to claim 4, wherein the clamping member further comprises a lead portion located at a joint portion between the butting portion and the main body, and used to guide the butting portion to enter the abutting member.

6. The isolation device according to claim 1, wherein each block corner of the abutting member and the clamping member is a round angle.

7. The isolation device according to claim 1, wherein the frame body further comprises a via portion, located on the body and used for a terminal member to pass through.

8. The isolation device according to claim 7, wherein the terminal member is fixed on the base body through tin soldering.

9. The isolation device according to claim 1, wherein the frame body further comprises a plurality of pins formed at block corners of the base body through stamping.

10. The isolation device according to claim 1, wherein the frame body is formed through stamping.
